(19) United States
(12) Patent Application Publication
(10) Pub. No.: US 2020/0403123 A1
(43) Pub. Date: Dec. 24, 2020

(54) SUBSTRATE FOR ELECTRIC ELEMENT AND MANUFACTURING METHOD THEREFOR

(71) Applicant: Samsung Electronics Co., Ltd., Suwon-si, Gyeonggi-do (KR)

(72) Inventors: Kyungwoon JANG, Suwon-si (KR); Changjoon LEE, Suwon-si (KR); Daesuck HWANG, Suwon-si (KR)

(21) Appl. No.: 16/977,776

(22) PCT Filed: Mar. 5, 2019
(86) PCT No.: PCT/KR2019/002491

§ 371 Date: Sep. 2, 2020

(30) Foreign Application Priority Data
Mar. 6, 2018 (KR) 10-2018-0026160

(51) Int. Cl. H01L 33/38; H01L 27/15; H01L 33/00

(52) U.S. Cl. CPC H01L 33/385; H01L 33/56; H01L 33/0093; H01L 27/156

(57) ABSTRACT

Various embodiments comprise: a substrate; a plurality of unit electric elements arranged on the substrate at regular intervals; and at least one conductive path electrically connected to each of the plurality of unit electric elements nearby and having an energized inspection area formed at an end thereof. It is possible to determine whether each of the plurality of unit electric elements is electrically good or defective by using an energized inspection area of the conductive path. Other various embodiments may be possible.

### CROSS-REFERENCE TO RELATED APPLICATIONS

This application is a 371 National Stage of International Application No. PCT/KR2019/002491, filed Mar. 5, 2019, which claims priority to Korean Patent Application No. 10-2018-0026160, filed Mar. 6, 2018, the disclosures of which are herein incorporated by reference in their entirety.

### BACKGROUND

### 1. Field

Various embodiments of the disclosure relate to a substrate for an electric element and a method for manufacturing the same, and more particularly to a substrate for a current flow inspection of an electric element and a method for manufacturing the same.

### 2. Description of Related Art

In recent years, electric elements such as micro LEDs tend to be replaced by pixels of displays. Because an existing long-distance display (e.g., an outdoor long-distance display) employs an LED package of a size of several millimeters, it is not suitable for short distances or homes. Accordingly, in order to realize a short-distance display, a problem of having to transfer an LED of several tens of μm to several hundred μm capable of coping with the current pixels to a substrate with precision and at a high yield rate should be solved in advance. The size of one pixel of a domestic display that is currently being developed is normally about 100 μm, and the size of an R/G/B sub-pixel is merely several tens of μm.

In recent years, although LEDs having sizes of several tens of μm corresponding to the size of the pixels applied to the above-described short-range display are manufactured in a deposition method through wafers, an inspection of the electrical qualities of the manufactured micro elements is very difficult due to the sizes.

### SUMMARY

In general, when fine chips such as micro LEDs are mounted in the form of flip chips, a method of directly transferring the chips from wafers to substrates due to the many disadvantages of the process may be used. In this case, although the excellent precision of the micro LEDs can be secured according to the pitch or size of the wafers formed through a semiconductor process, a method for sorting and mounting known good dies (KGDs) inspected in the wafers may be required. Although an inspection of the light emission efficiencies and wavelengths of the micro LED wafers may be performed through a photo luminescence (P/L) inspection, an inspection of the electrical qualities of the micro LED wafers in a conventional probing scheme is very difficult in reality because the determination of the electrical qualities performed by actually applying electrical signals is difficult due to the sizes and connection structures of the pads thereof.

Various embodiments of the disclosure may provide a substrate for an electric element and a method for manufacturing the same.

Various embodiments may provide a substrate for an electric element that may perform an inspection of electrical qualities during an electric element manufacturing process, and a method for manufacturing the same.

Various embodiments may provide a substrate for an electric element that may improve the yield rate of a product by performing an inspection of electrical qualities during an electric element manufacturing process, before a substrate is mounted, and enhance the efficiency of an operation process, and a method for manufacturing the same.

In accordance with an aspect of the disclosure, there is provided a substrate including a base substrate layer, a plurality of unit electric elements arranged on the base substrate layer at a predetermined interval, and one or more conductive paths electrically connected to the plurality of unit electric elements around the plurality of unit electric elements, respectively, and each of which has a current flow inspection area at an end thereof, wherein the electrical qualities of the plurality of unit electric elements are determined by using the current flow inspection areas of the conductive paths.

In accordance with another aspect of the disclosure, there is provided a carrier substrate including a substrate, a plurality of micro LEDs arranged on the substrate at a predetermined interval, and one or more conductive paths electrically connected to the plurality of micro LEDs around the plurality of micro LEDs, respectively, and having current flow inspection areas at ends thereof, and the electrical qualities of the plurality of micro LEDs may be determined by using current flow inspection areas of the conductive paths.

In accordance with another aspect of the disclosure, there is provided a method for manufacturing a carrier substrate including forming a plurality of light emitting layers in a base substrate layer, forming one or more conductive paths such that the conductive paths are electrically connected in common to the plurality of light emitting layers around the light emitting layers, transferring the conductive paths and the light emitting layers to the carrier substrate, dividing the light emitting layers transferred to the carrier substrate into a plurality of unit micro LEDs, and performing a current flow inspection for determining the qualities of the divided micro LEDs through the one or more conductive paths.

According to various embodiments of the disclosure, an efficient operation can be performed because electrical qualities can be inspected during an electric element manufacturing process. In particular, because the electrical qualities of micro LEDs can be determined before the micro LEDs are mounted on a display substrate, the yield rate of the product and the efficiency of the manufacturing time can be increased.

### BRIEF DESCRIPTION OF THE DRAWINGS

FIG. 1 is a view illustrating a configuration of a display, to which micro LEDs are applied, according to various embodiments of the disclosure.

FIG. 2 is a flowchart illustrating a process of manufacturing micro LEDs according to various embodiments of the disclosure.

FIGS. 3A to 3I are diagrams illustrating a process sequence of the micro LEDs manufactured through the process of FIG. 2 according to various embodiments of the disclosure.

FIGS. 4A and 4B are views illustrating a state in which micro LEDs disposed in a carrier substrate are separated by a pickup device according to various embodiments of the disclosure.

### DETAILED DESCRIPTION

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used herein, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software including one or more instructions that are stored in a storage medium that is readable by a machine. For example, a processor of the machine may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

Hereafter, a method for manufacturing a display, which includes a micro LED current flow inspection, according to various embodiments of the disclosure will be described with reference to the accompanying drawings.

Because a configuration of a display according to an exemplary embodiment of the disclosure is realized regardless of the sizes of LEDs, the sizes of the used LEDs are not limited. For example, a display for lighting may employ LEDs of several millimeters, a large-scale display such as indoor/outdoor signages may employ LEDs of several hundred micrometer LEDs, and a short-range display may employ LEDs of several tens of micrometers.

Further, although methods for inspecting current flows of micro LEDs and manufacturing micro LEDs are illustrated and described in the exemplary embodiments of the disclosure, the disclosure is not limited thereto. For example, the disclosure may be applied to various electric elements that may use the current flow inspection and the manufacturing method.

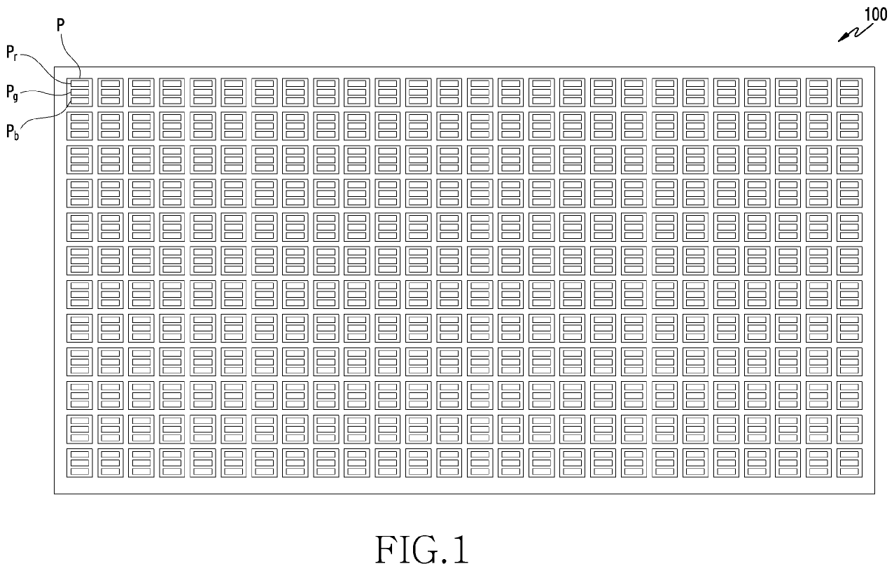

FIG. 1 is a view illustrating a configuration of a display, to which micro LEDs are applied, according to various embodiments of the disclosure.

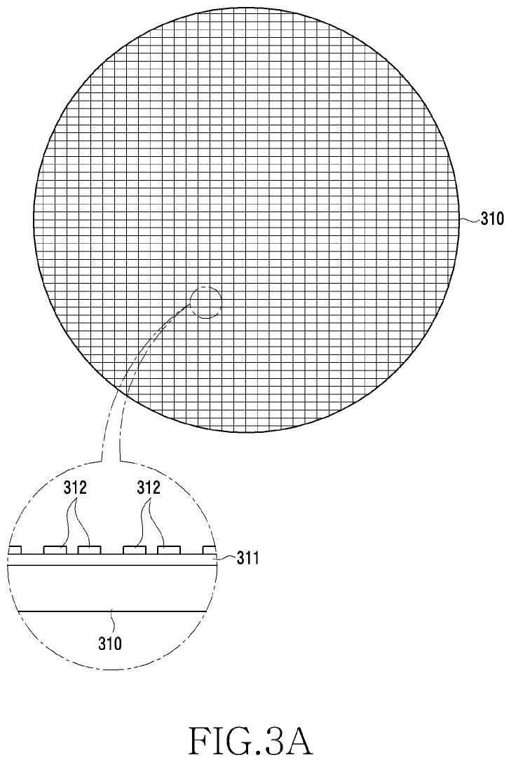

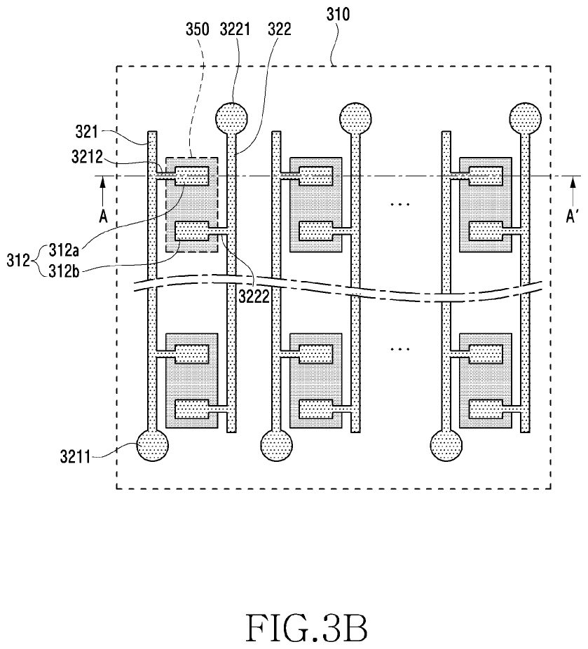

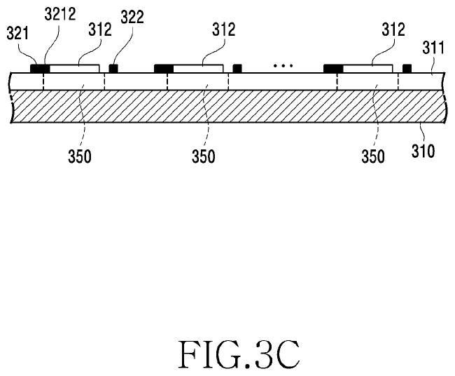

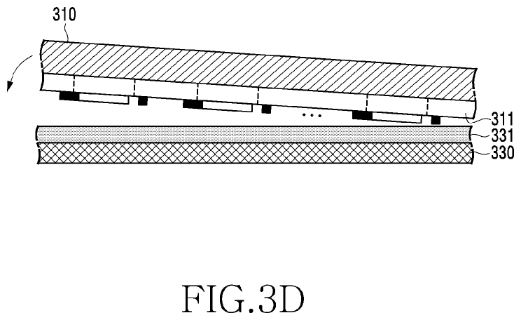

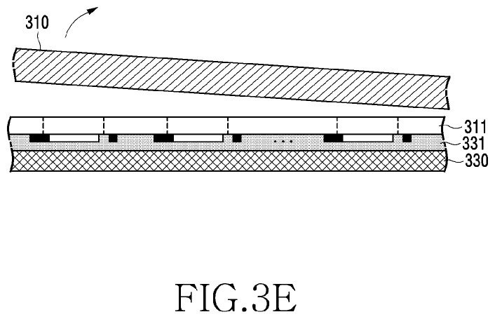

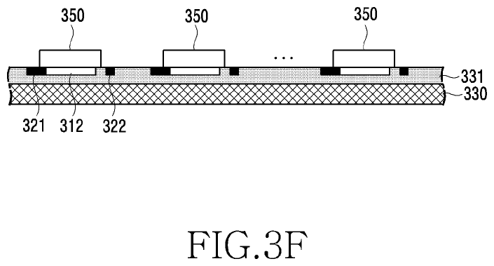

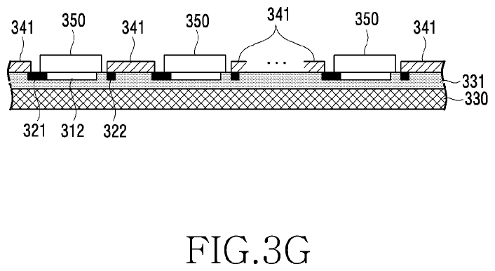

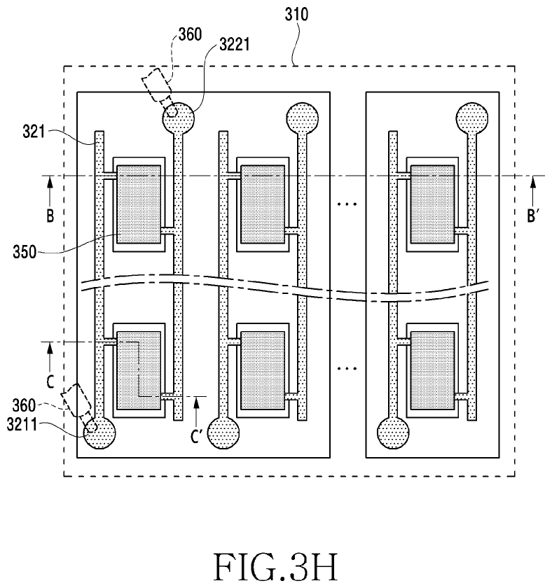

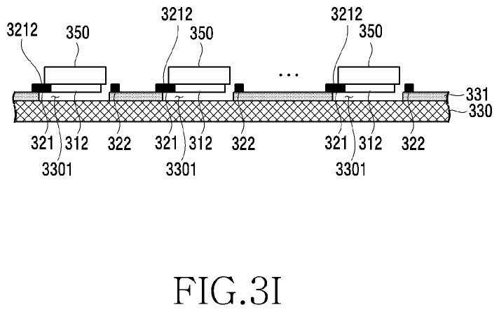

Referring to FIG. 1, a display 100 may include a plurality of pixels P disposed at a predetermined interval. According to an embodiment, the unit pixels P may include sub-pixels Pr, Pg, and Pb. According to an embodiment, the sub-pixels Pr, Pg, and Pb, for example, may be micro LEDs (e.g., the micro LEDs 350 of FIG. 3B) having an area of 10000 μm² or less.

According to various embodiments, before the micro LEDs are mounted on the substrate of the display 100, a current flow inspection for determining the electrical qualities of the micro LEDs may be performed in advance. According to an embodiment, because the micro LEDs, on which the current flow inspection is performed, are mounted on the substrate of the display 100, the yield rate of the display 100 can be increased.

Hereinafter, a process of manufacturing micro LEDs corresponding to the sub-pixels of the display will be described.

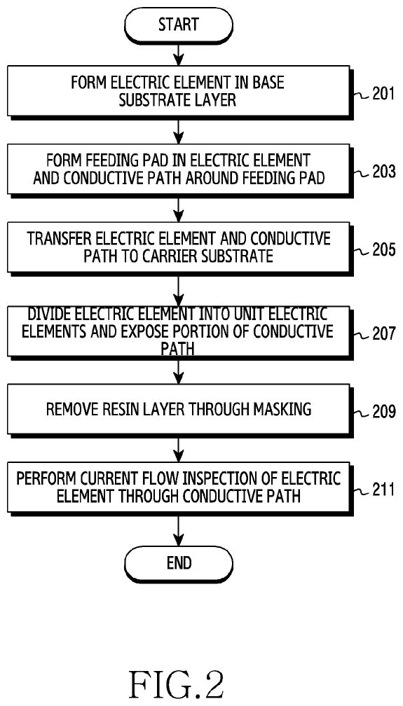

FIG. 2 is a flowchart illustrating a process of manufacturing micro LEDs according to various embodiments of the disclosure. FIGS. 3A to 3I are diagrams illustrating a process sequence of the micro LEDs manufactured through the process of FIG. 2 according to various embodiments of the disclosure.

Referring to FIG. 2, in operation 201, as illustrated in FIG. 3A, micro LEDs (e.g., electric elements) may be formed in a base substrate layer 310 (e.g., a sapphire wafer). According to an embodiment, the micro LED may include a light emitting layer 311 deposited on the base substrate layer 310 before being divided into unit electric elements. According to an embodiment, the light emitting layer 311 may be formed to grow in a single crystal state of a composite semiconductor in a high-temperature/high-pressure state in a sapphire or SiX base substrate layer 310, and the color of the light emitting layer 311 may vary according to the composition thereof. For example, a red color may be realized by a composite semiconductor of GaAs, a green color may be realized by a composite semiconductor of InGap, and a blue color may be realized by a composite semiconductor of GaN, and the wavelength of the light emitting layer 311 may be determined according to the natural energy bandgap values of the compositions and thus the color of the light emitting layer 311 may vary.

In operation 203, a feeding pad 312 and one or more conductive paths 321 and 322 may be formed in the feeding pad 312 and around the feeding pad 312 may be formed on the light emitting layer 311. FIG. 3B is a plan view of a base substrate layer 310, in which the feeding pad 312 and the conductive paths 321 and 322 are formed in the light emitting layer, and FIG. 3C is a cross-sectional view of the base substrate layer 310 viewed from line A-A′ of FIG. 3B.

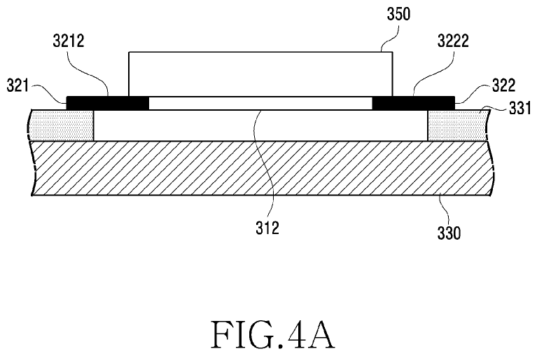

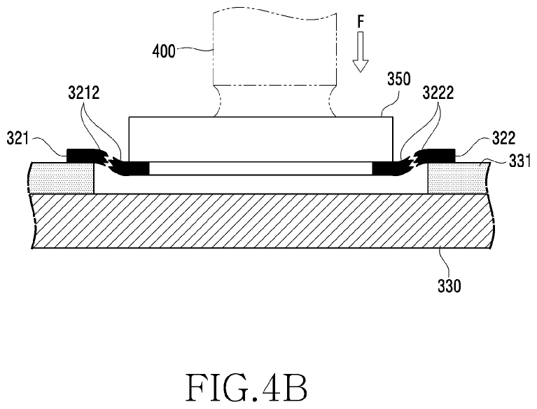

According to various embodiments, as illustrated in FIGS. 3B and 3C, the micro LEDs 350 may be arranged on the base substrate layer 310 at a predetermined interval. According to an embodiment, the micro LEDs 350 may be disposed on the base substrate layer 310 along rows and/or columns at a predetermined interval. According to an embodiment, each of the micro LEDs 350 may include one or more feeding pads 312 formed such that the micro LED 350 is electrically connected to a conductive pad (e.g., the conductive pad 441 of FIG. 4) of a display substrate (e.g., the display substrate 440 of FIG. 4) in the base substrate layer 310 before the micro LED 350 is divided into unit micro LEDS. According to an embodiment, the feeding pads 312 may include a first feeding pad 312a and a second feeding pad 312b that is spaced apart from the first feeding pad 312a at a predetermined interval.

According to various embodiments, the one or more conductive paths 321 and 322 may include a first conductive path 321 disposed on one side of the plurality of micro LEDs arranged in rows and/or columns, and a second conductive path 322 disposed on an opposite side thereof. According to an embodiment, the first conductive path 321 and the second conductive path 322 may be disposed to extend along the rows and/or rows of the plurality of micro LEDs 350 in the base substrate layer 310. According to an embodiment, the first conductive path 321 and the second conductive path 322 may be formed together when the feeding pads 312 are formed. According to an embodiment, the first conductive path 321 and the second conductive path 322 may be electrically connected to the feeding pads 312 of the micro LEDs 350 arranged in rows and/or columns at the same time. For example, the first feeding pad 312a of each of the plurality of micro LEDs 350 may be electrically connected to the first conductive path 321 through the first sub-electrical path 3212. The second feeding pad 312b of each of the plurality of micro LEDs 350 according to an embodiment may be electrically connected to the second conductive path 322 through the second sub-electrical path 3222. According to an embodiment, a first current flow inspection area 3211 may be disposed at one end of the first conductive path 321. According to an embodiment, a second current flow inspection area 3221 may be disposed at one end of the second conductive path 322. The first current flow inspection area 3211 and the second current flow inspection area 3221 may contribute as probe contact areas for a current flow inspection for determining the electrical quality.

In operation 205, the micro LEDs 350 (e.g., the electric elements) and the one or more conductive paths 321 and 322 may be transferred to a carrier substrate 330. According to an embodiment, as illustrated in FIG. 3D, the light emitting layers 331, the feeding pads 312, and the conductive paths 321 and 322 may be transferred (e.g., attached) to the carrier substrate 330 (e.g., a carrier film) in which a resin layer 331 (e.g., a bonding layer) is disposed. According to an embodiment, a method for transferring the micro LEDs 350 and the conductive paths 321 and 322 to the carrier substrate 330 may be at least one of a method of using an uncured resin (liquid polyimide (PI)), polydimethylsiloxane (PDMS), polyethylene terephthalate (PET), epoxy, or the like) or methods of using a difference of the adhering forces of film type tapes such as an ultraviolet (UV) tape, a non-UV tape, or a thermally expandable tape.

In operation 207, the base substrate layer 310 may be removed from the carrier substrate 330, the plurality of micro LEDs 350 (e.g., the electric elements) are divided into unit micro LEDs 350 through an etching process, and the one or more conductive paths 321 and 322 may be exposed from the carrier substrate 330.

According to various embodiments, as illustrated in FIGS. 3E and 3F, the base substrate layer 310 may be separated from the light emitting layers 311 of the carrier substrate 330. According to an embodiment, the base substrate layer 310 may be separated from the carrier substrate 330 through a laser lift-off (LLO) process. An eximer or a DPSS may be used as the laser. According to an embodiment, a singulation process may be performed on the light emitting layers 311 to form individual micro LEDs 350. According to an embodiment, the light emitting layers 311 may be divided into unit micro LEDs 350 through an etching process. According to an embodiment, each of the unit micro LEDs 350 may include a feeding pad 312, and the feeding pad 312 may be electrically connected in common to the one or more conductive paths 321 and 322. The one or more conductive paths 321 and 322 may be disposed while being exposed from an upper portion of the resin layer 331 through an etching process.

In operation 209, the resin layer 331 may be partially removed from the carrier substrate 330 divided into the unit micro LEDs 350. According to an embodiment, as illustrated in FIG. 3G, the mask 341 may be disposed between at least some of the first conductive paths 321 and the adjacent second conductive paths 322. According to an embodiment, the resin layer 331 on the carrier substrate 330 may be at least partially removed through a masking process.

In operation 211, the current flow inspection for determining the qualities of the micro LEDs 350 may be performed through the conductive paths 321 and 322. FIG. 3H is a plan view of the carrier substrate 330, on which a masking operation has been performed, and FIG. 3I is a cross-sectional view of the carrier substrate 330 viewed from line B-B′ of FIG. 3I.

According to an embodiment, if the resin layer 331 is at least partially removed through a masking process, the unit micro LEDs 350 may maintain a floated state while a specific space 3301 from the carrier substrate 330 on the lower side thereof is provided. According to an embodiment, the micro LEDs 350 may maintain a floated state in an anchor and tether structure on the space 3301, from which the resin layer has been removed, through the sub-electrical paths 3212 and 3222 branched from the conductive paths 321 and 322 and connected to the feeding pads 312 of the micro LEDs 350. According to an embodiment, a current flow inspection for determining the electrical qualities of the micro LEDs 350 may be performed by performing an electrical probing process by using the one or more conductive paths 321 and 322. For example, as a probe 360 for current flows contacts a first current flow inspection area 3211 (e.g., a (+) current application area) of the first conductive path 321 and a second current flow inspection area 3221 (e.g., a (−) current application area) of the second conductive path 322, current may flow through the unit micro LEDs 350. According to an embodiment, although a normal micro LED may emit light through a current flow inspection for determining the electrical quality of the micro LED, an abnormal micro LED may not emit light. According to an embodiment, the micro LED that is determined to be defective may be removed or may be excluded from a pickup process through information on a location of the carrier substrate 330.

According to various embodiments, the micro LEDs 350 floated in an anchor and tether structure on the carrier substrate 330 may be mounted on the display substrate through a pickup device.

FIGS. 4A and 4B are views illustrating a state in which micro LEDs 350 disposed in a carrier substrate 330 are separated by a pickup device 440 according to various embodiments of the disclosure.

FIGS. 4A and 4B are cross-sectional view viewed from line C-C′ of FIG. 3H.

Referring to FIGS. 4A and 4B, the micro LEDs 350 in which the resin layer 331 is partially removed from the carrier substrate 330 and which are floated to have an anchor and tether structure through the sub-electrical paths 3212 and 3211 branched from the electrical paths 321 and 322 may be picked up by the pickup device 400. In this case, the micro LEDs 350 may be picked up by a pickup force F of the pickup device 400 while the sub-electrical paths 3212 and 3222 are broken. For example, the sub-electrical paths 3212 and 3222 may be interrupted from the conductive paths 321 and 322 after the current flow inspection of the electrical qualities of the micro LEDs 350 are performed. Accordingly, the sub-electrical paths 3212 and 3222 that electrically connect the conductive paths 321 and 322 and the feeding pads 312 of the micro LEDs 350 may be used for an inspection of the electrical qualities, and may contribute to floating disposition of the micro LEDs 350 by the anchor and tether structure due to removal of the resin layer 331 between the carrier substrate 330 and the micro LEDs 350.

According to various embodiments, a substrate may include a base substrate layer, a plurality of unit electric elements arranged on the base substrate layer at a predetermined interval, and one or more conductive paths electrically connected to the plurality of unit electric elements around the plurality of unit electric elements, respectively, and each of which has a current flow inspection area at an end thereof, wherein the electrical qualities of the plurality of unit electric elements are determined by using the current flow inspection areas of the conductive paths.

According to various embodiments, each of the plurality of unit electric elements may have a micro LED having an area of a range of 10000 μm² or less.

According to various embodiments, the substrate may include a resin layer disposed between the base substrate layer and the plurality of unit electric elements, and one or more feeding pads disposed in the plurality of unit electric elements, respectively, and the feeding pads may be electrically connected to the one or more conductive paths.

According to various embodiments, the substrate may include one or more sub-electric paths branched from the conductive paths and extending to the feeding pads corresponding to the plurality of unit electric elements.

According to various embodiments, the resin layer between the plurality of unit electric elements and the base substrate layer may be removed, and the plurality of unit electric elements may be floated in an anchor and tether structure through the one or more sub-electric path.

According to various embodiments, the base substrate layer may include a carrier substrate, to which a micro LED is transferred.

According to various embodiments, the plurality of unit electric elements may be disposed in rows and/or columns at a predetermined interval, and the one or more conductive paths are disposed to extend along the rows and/or columns around the unit electric elements.

According to various embodiments, a carrier substrate may include a substrate, a plurality of micro LEDs arranged on the substrate at a predetermined interval, and one or more conductive paths electrically connected to the plurality of micro LEDs around the plurality of micro LEDs, respectively, and having current flow inspection areas at ends thereof, and the electrical qualities of the plurality of micro LEDs may be determined by using current flow inspection areas of the conductive paths.

According to various embodiments, the areas of the plurality of micro LEDs may be 10000 μm² or less.

According to various embodiments, the carrier substrate may include resin layers disposed between the substrate and the plurality of micro LEDS, and one or more feeding pads disposed in the plurality of micro LEDs, respectively, and the feeding pads may be electrically connected to the one or more conductive paths.

According to various embodiments, the carrier substrate may include one or more sub-electrical paths branched from the conductive paths and extending to the feeding pads corresponding to the plurality of divided micro LEDs.

According to various embodiments, the resin layer may be removed between the plurality of micro LEDs and the substrate, and the plurality of micro LEDs may be floated in an anchor and tether structure through the one or more sub-electric path.

According to various embodiments, the plurality of electric elements are disposed on the substrate in rows and/or columns at a predetermined interval, and the one or more conductive paths may be disposed to extend along the rows and/or columns around the micro LEDs.

According to various embodiments, a method for manufacturing a carrier substrate may include forming a plurality of light emitting layers in a base substrate layer, forming one or more conductive paths such that the conductive paths are electrically connected in common to the plurality of light emitting layers around the light emitting layers, transferring the conductive paths and the light emitting layers to the carrier substrate, dividing the light emitting layers transferred to the carrier substrate into a plurality of unit micro LEDs, and performing a current flow inspection for determining the qualities of the divided micro LEDs through the one or more conductive paths.

According to various embodiments, the method may include transferring the conductive paths and the light emitting layers to the carrier substrate by using a resin layer.

According to various embodiments, the method may include removing at least a portion of the resin layer, and the divided micro LEDs may be floated from the carrier substrate by the removed resin layer and the one or more conductive paths.

According to various embodiments, the removing of the resin layer may include removing a portion of the resin layer, which overlaps at least a portion of the conductive path, through a masking process.

According to various embodiments, the method may include one or more sub-electric paths branched from the conductive paths and extending to the feeding pads corresponding to the plurality of divided micro LEDs, and the plurality of micro LEDs are floated in an anchor and tether structure through the one or more sub-electric path.

According to various embodiments, the plurality of divided micro LEDs may be disposed along rows and/or columns on the carrier substrate at a predetermined interval, and the one or more conductive paths may be disposed to extend along the rows and/or columns around the micro LEDs.

According to various embodiments, each of the micro LEDs may have one or more feeding pad, and the one or more conductive paths may be formed together when the feeding pads are formed.

The embodiments described and shown in the specification and the drawings have presented specific examples in order to easily explain the technical contents of embodiments and help understanding of embodiments, and are not intended to limit the scope of embodiments. Therefore, the scope of various embodiments should be construed to include, in addition to the embodiments disclosed herein, all changes and modifications that are derived on the basis of the technical idea of various embodiments.

1. A substrate comprising:
a base substrate layer;
a plurality of unit electric elements arranged on the base substrate layer at a predetermined interval; and
one or more conductive paths electrically connected to the plurality of unit electric elements around the plurality of unit electric elements, respectively, and each of which has a current flow inspection area at an end thereof,
wherein the electrical qualities of the plurality of unit electric elements are determined by using the current flow inspection areas of the conductive paths.

2. The substrate of claim 1, wherein each of the plurality of unit electric elements has a micro LED having an area of a range of 10000 μm² or less.

3. The substrate of claim 1, further comprising:
a resin layer disposed between the base substrate layer and the plurality of unit electric elements; and
one or more feeding pads disposed in the plurality of unit electric elements, respectively,
wherein the feeding pads are electrically connected to the one or more conductive paths.

4. The substrate of claim 3, further comprising:
one or more sub-electric paths branched from the conductive paths and extending to the feeding pads corresponding to the plurality of unit electric elements.

5. The substrate of claim 3, wherein the resin layer between the plurality of unit electric elements and the base substrate layer are removed, and
wherein the plurality of unit electric elements are floated in an anchor and tether structure through the one or more sub-electric path.

6. The substrate of claim 1, wherein the base substrate layer comprises a carrier substrate, to which a micro LED is transferred.

7. The substrate of claim 6, wherein the plurality of unit electric elements are disposed in rows and/or columns at a predetermined interval, and
wherein the one or more conductive paths are disposed to extend along the rows and/or columns around the unit electric elements.

8. The substrate of claim 1, wherein each of the unit electric elements comprises a micro LED.

9. A method for manufacturing a carrier substrate, the method comprising:
forming a plurality of light emitting layers in a base substrate layer;
forming one or more conductive paths such that the conductive paths are electrically connected in common to the plurality of light emitting layers around the light emitting layers;
transferring the conductive paths and the light emitting layers to the carrier substrate;
dividing the light emitting layers transferred to the carrier substrate into a plurality of unit micro LEDs; and
performing a current flow inspection for determining the qualities of the divided micro LEDs through the one or more conductive paths.

10. The method of claim 9, further comprising:
transferring the conductive paths and the light emitting layers to the carrier substrate by using a resin layer.

11. The method of claim 10, further comprising:
removing at least a portion of the resin layer,
wherein the divided micro LEDs are floated from the carrier substrate by the removed resin layer and the one or more conductive paths.

12. The method of claim 11, wherein the removing of the resin layer comprises:
removing a portion of the resin layer, which overlaps at least a portion of the conductive path, through a masking process.

13. The method of claim 12, further comprising:
forming one or more sub-electric paths branched from the conductive paths and extending to the feeding pads corresponding to the plurality of divided micro LEDs,
wherein the plurality of micro LEDs are floated in an anchor and tether structure through the one or more sub-electric path.

14. The method of claim 9, wherein the plurality of divided micro LEDs are disposed along rows and/or columns on the carrier substrate at a predetermined interval, and
wherein the one or more conductive paths are disposed to extend along the rows and/or columns around the micro LEDs.

15. The method of claim 10, wherein each of the micro LEDs has one or more feeding pad, and
wherein the one or more conductive paths are formed together with the feeding pads are formed.

16. A carrier substrate comprising:
a base substrate layer;
a plurality of micro LEDs arranged on the base substrate layer at a predetermined interval; and
one or more conductive paths electrically connected to the plurality of micro LEDs around the plurality of micro LEDs, respectively, and each of which has a current flow inspection area at an end thereof,
wherein the electrical qualities of the plurality of micro LEDs are determined by using the current flow inspection areas of the conductive paths.

17. The carrier substrate of claim 16, wherein each of the plurality of micro LEDs have an area of a range of 10000 μm2 or less.

18. The carrier substrate of claim 16, further comprising:
a resin layer disposed between the base substrate layer and the plurality of micro LEDs; and
one or more feeding pads disposed in the plurality of micro LEDs, respectively,
wherein the feeding pads are electrically connected to the one or more conductive paths.

19. The carrier substrate of claim 18, further comprising:
one or more sub-electric paths branched from the conductive paths and extending to the feeding pads corresponding to the plurality of micro LEDs.

20. The carrier substrate of claim 19, wherein the resin layer between the plurality of micro LEDs and the base substrate layer are removed, and
wherein the plurality of micro LEDs are floated in an anchor and tether structure through the one or more sub-electric path.
